(19) United States
(12) Patent Application Publication
(10) Pub. No.: US 2026/0096226 A1
(43) Pub. Date: Apr. 2, 2026

(54) ELECTROSTATIC DISCHARGE PROTECTION STRUCTURE AND ELECTROSTATIC DISCHARGE PROTECTION CIRCUIT

(71) Applicant: Winbond Electronics Corp., Taichung City (TW)

(72) Inventor: Chao-Lung Wang, Taichung City (TW)

(73) Assignee: Winbond Electronics Corp., Taichung City (TW)

(21) Appl. No.: 19/017,777

(22) Filed: Jan. 13, 2025

(30) Foreign Application Priority Data
Sep. 27, 2024 (TW) 113137097

(51) Int. Cl. H10D 89/60; H02H 9/04

(52) U.S. Cl. CPC H10D 89/811; H10D 89/911; H02H 9/04

(57) ABSTRACT

An electrostatic discharge (ESD) protection structure and an ESD protection circuit are provided. The ESD protection structure includes a substrate, a though silicon via (TSV), a liner oxide layer, a first heavily doped region, and a second heavily doped region. The substrate is coupled to a first voltage rail. The TSV is formed in the substrate. The liner oxide layer surrounds a side surface of the TSV. The first heavily doped region is formed in the substrate and contacts a first side of the liner oxide layer. The second heavily doped region is formed in the substrate and contacts a second side of the liner oxide layer. The first heavily doped region is coupled to the TSV through a transmission conductive wire, and the second heavily doped region is coupled to a second voltage rail.

### CROSS-REFERENCE TO RELATED APPLICATION

This application claims the priority benefit of Taiwan application serial no. 113137097, filed on Sep. 27, 2024. The entirety of the above-mentioned patent application is hereby incorporated by reference herein and made a part of this specification.

### BACKGROUND

### Technical Field

The disclosure relates to an electrostatic discharge protection structure and an electrostatic discharge protection circuit, and in particular to an electrostatic discharge protection structure and an electrostatic discharge protection circuit that reduce a layout area.

### Description of Related Art

With the advancement of electronic technology, semiconductor chips have become important tools in people's daily lives. In order to increase the layout density of semiconductor chips, stacked semiconductor chips have become an important trend in current chip layout.

To complete the action of chip stacking, through-silicon vias (TSVs) are often used as connection media between chips. In order to set up an electrostatic discharge protection mechanism on TSVs, it is necessary to arrange ESD protection elements for each TSV. Since the number of TSVs may be large, how to reduce the circuit layout area required for the ESD protection elements has become an important issue for designers.

### SUMMARY

The disclosure provides an electrostatic discharge protection structure and an electrostatic discharge protection circuit, which reduce a required circuit layout area.

An electrostatic discharge protection structure includes a substrate, a through-silicon via, a liner oxide layer, a first heavily doped region, and a second heavily doped region. The substrate is coupled to a first voltage rail. The through-silicon via is formed in the substrate. The liner oxide layer surrounds the side surface of the through-silicon via. The first heavily doped region is formed in the substrate and contacts a first side of the liner oxide layer. The second heavily doped region is formed in the substrate and contacts a second side of the liner oxide layer. The first heavily doped region is coupled to the through-silicon via through a transmission conductive wire, and the second heavily doped region is coupled to a second voltage rail through a second transmission conductive wire.

An electrostatic discharge protection circuit includes a transistor. The transistor is formed on a substrate, and a source of the transistor is coupled to a gate of the transistor and coupled to an input/output port. The substrate is coupled to a first voltage rail, and a drain of the transistor is coupled to a second voltage rail. The transistor includes a through-silicon via, a liner oxide layer, a first heavily doped region, and a second heavily doped region. The through-silicon via is formed in the substrate and used to form the gate of the transistor. The liner oxide layer surrounds a side surface of the through-silicon via and is used to form a gate oxide layer of the transistor. The first heavily doped region is formed in the substrate and contacts a first side of the liner oxide layer. The first heavily doped region is used to form the source of the transistor. The second heavily doped region is formed in the substrate and contacts a second side of the liner oxide layer. The second heavily doped region is used to form the drain of the transistor.

Based on the above, the through-silicon via coupled to the input/output port directly forms the gate of the transistor in the electrostatic discharge circuit. By forming the through-silicon via in the substrate and forming multiple heavily doped regions on the substrate to create the source and drain of the transistor, the circuit layout area of the transistor as part of the electrostatic discharge protection structure can be effectively reduced, thus lowering the production cost of the circuit.

### BRIEF DESCRIPTION OF THE DRAWINGS

FIG. 1 shows a top view of an electrostatic discharge (ESD) protection structure according to an embodiment of the disclosure.

FIG. 2 shows a cross-sectional diagram of an ESD protection structure 100 of the embodiment in FIG. 1 along line A-A′.

FIG. 3 shows a schematic diagram of the ESD protection structure according to another embodiment of the disclosure.

FIG. 4 shows a schematic diagram of the ESD protection circuit according to an embodiment of the disclosure.

FIGS. 5A and 5B show schematic diagrams of the ESD protection action of the ESD protection circuit according to an embodiment of the disclosure.

### DESCRIPTION OF THE EMBODIMENTS

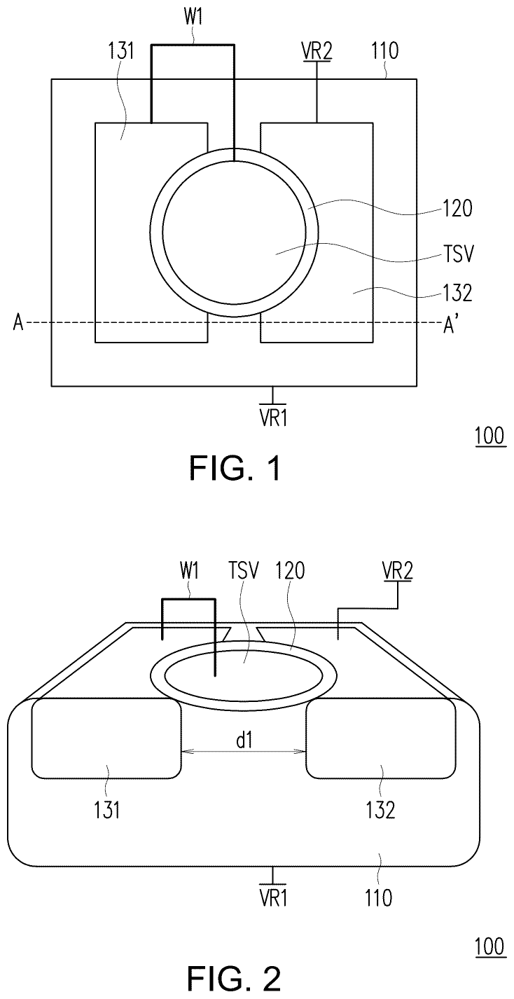

Please refer to FIG. 1, which shows a top view of the electrostatic discharge (ESD) protection structure according to an embodiment of the disclosure. An ESD protection structure 100 includes a substrate 110, a through-silicon via (TSV), a liner oxide layer 120, and heavily doped regions 131 and 132. The TSV can be formed in the substrate 110. The liner oxide layer 120 is also formed in the substrate 110 and surrounds the side surface of the TSV. The liner oxide layer 120 is used to electrically isolate the TSV from the substrate 110.

Additionally, the heavily doped regions 131 and 132 are respectively formed in different areas of the substrate 110. The heavily doped region 131 is in contact with a first side of the liner oxide layer 120, and the heavily doped region 132 is in contact with a second side of the liner oxide layer 120. It is noteworthy that the heavily doped region 131 and the heavily doped region 132 do not contact each other.

In this embodiment, the TSV can extend outwards from the substrate 110 (for example, in the direction out of the plane of the drawing) and be coupled to an input/output port of the circuit. The TSV formed inside the substrate 110 can form a gate of a transistor, while the liner oxide layer 120 is used to form a gate oxide layer of this transistor. The heavily doped regions 131 and 132 respectively form a source and a drain of the transistor. The heavily doped region 131 can be coupled to the TSV through a transmission conductive wire W1. In other words, the gate of the transistor can be electrically connected to the source of the transistor.

On the other hand, the heavily doped region 132 can be electrically connected to a second voltage rail VR2, and the substrate 110 can be electrically connected to a first voltage rail VR1. In the circuit, the first voltage rail VR1 can be used to receive a power supply voltage, while the second voltage rail VR2 can receive a reference ground voltage.

It is worth mentioning that, the heavily doped regions 131 and 132 can have the same conductive polarity. The substrate 110 can have a conductive polarity different (opposite) from that of the heavily doped region 131. For example, the substrate 110 can be an N-type well, while the heavily doped regions 131 and 132 can be P+ type heavily doped regions.

Please refer to FIG. 2, which shows a cross-sectional diagram of the electrostatic discharge (ESD) protection structure 100 of the embodiment in FIG. 1 along line A-A′. In FIG. 2, the heavily doped regions 131 and 132 can be disposed on two different sides of the substrate 110. There can be a spacing distance dl between the heavily doped regions 131 and 132. When there is a certain degree of voltage difference between the substrate 110 and the TSV, a channel can form between the heavily doped regions 131 and 132.

The substrate 110 can be coupled to the first voltage rail VR1 to receive a power supply voltage, and the heavily doped region 132 can be coupled to the second voltage rail VR2 to receive a reference ground voltage. The TSV can extend upwards and be coupled to the input/output port. The TSV can also be coupled to the heavily doped region 131 through the transmission conductive wire W1.

When a surge voltage is applied to the input/output port, an electrostatic discharge phenomenon is generated. If the surge voltage has a positive pulse, the electrostatic discharge current corresponding to the surge voltage can be discharged through the heavily doped region 131 and through the substrate 110 to the first voltage rail VR1. Conversely, if the surge voltage has a negative pulse, a channel can form between the heavily doped regions 131 and 132, and the electrostatic discharge current corresponding to the surge voltage can be discharged through the channel between the heavily doped regions 131 and 132 to the second voltage rail VR2. In this way, the electrostatic discharge current generated by the electrostatic discharge phenomenon can be effectively discharged, achieving the effect of electrostatic discharge protection.

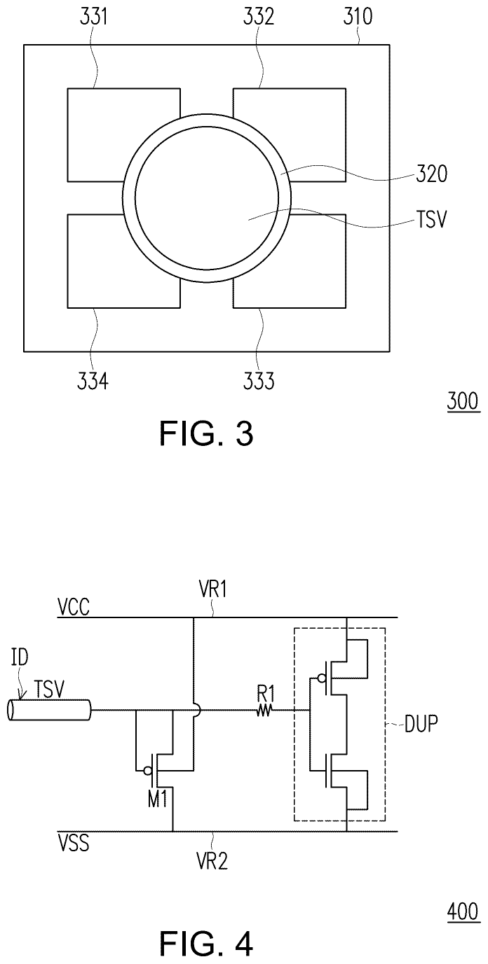

Please refer to FIG. 3, which shows a schematic diagram of the electrostatic discharge protection structure according to another embodiment of the disclosure. An ESD protection structure 300 includes a substrate 310, a TSV, a liner oxide layer 320, and heavily doped regions 331, 332, 333, and 334. The TSV can be formed in the substrate 310. The liner oxide layer 320 is also formed in the substrate 310 and surrounds the side surface of the TSV. The liner oxide layer 320 is used to electrically isolate the TSV from the substrate 310.

Additionally, the heavily doped regions 331 to 334 are respectively formed in different areas of the substrate 310. The heavily doped regions 331 to 334 are respectively in contact with multiple different sides of the liner oxide layer 320. It is noteworthy that the heavily doped regions 331, 332, 333, and 334 do not contact each other.

It is noteworthy that, the heavily doped regions 331 and 333 can be coupled to the TSV together through a transmission conductive wire. The heavily doped regions 332 and 334 can also be coupled together to the same second voltage rail. The heavily doped regions 331 and 333 together form the source of the transistor, while the heavily doped regions 332 and 334 together form the drain of the transistor. In other words, the heavily doped regions 331 and 333, which form the source, and the heavily doped regions 332 and 334, which form the drain, are alternately arranged around the liner oxide layer 320. When the TSV and the substrate 310 are appropriately biased (when the voltage on the substrate 310 is greater than the voltage on the TSV by a threshold value), multiple channels can form between the heavily doped region 331 and surrounding the heavily doped regions 332 and 334, and multiple channels can also form between the heavily doped region 333 and surrounding the heavily doped regions 332 and 334.

It is noteworthy that, the number of heavily doped regions serving as the source of the transistor can be more than two. Similarly, the number of heavily doped regions serving as the drain of the transistor can also be more than two. In practical applications, in the ESD protection structure, the number of heavily doped regions serving as the source of the transistor can be one or more, and the number of heavily doped regions serving as the drain of the transistor can also be one or more, without specific limitations. Furthermore, the number of heavily doped regions serving as the source of the transistor may or may not be the same as the number of heavily doped regions serving as the drain of the transistor, without specific limitations.

Please refer to FIG. 4, which shows a schematic diagram of the ESD protection circuit according to an embodiment of the disclosure. An ESD protection circuit 400 includes a transistor M1 and a resistor R1. The source of transistor M1 is coupled to the TSV; the drain of transistor M1 is coupled to the second voltage rail VR2; the substrate of transistor M1 is coupled to the first voltage rail VR1; and the gate of transistor M1 is formed by the TSV and extends to be coupled to an input/output node IO.

The first voltage rail VR1 is used to transmit a power supply voltage VCC, while the second voltage rail VR2 is used to transmit a reference ground voltage VSS.

The resistor R1 is coupled between the source of transistor M1 and a protected element DUP. During the electrostatic discharge protection process, resistor R1 can be used to slow down the rate at which the electrostatic discharge current flows to the protected element DUP, allowing transistor M1 sufficient time to be effectively turned on and complete the discharge of the electrostatic discharge current.

Transistor M1 can be formed using the ESD protection structure described in the embodiments of FIGS. 1, 2, and 3. The relevant details have been described in the previous embodiments, and will not be repeated here.

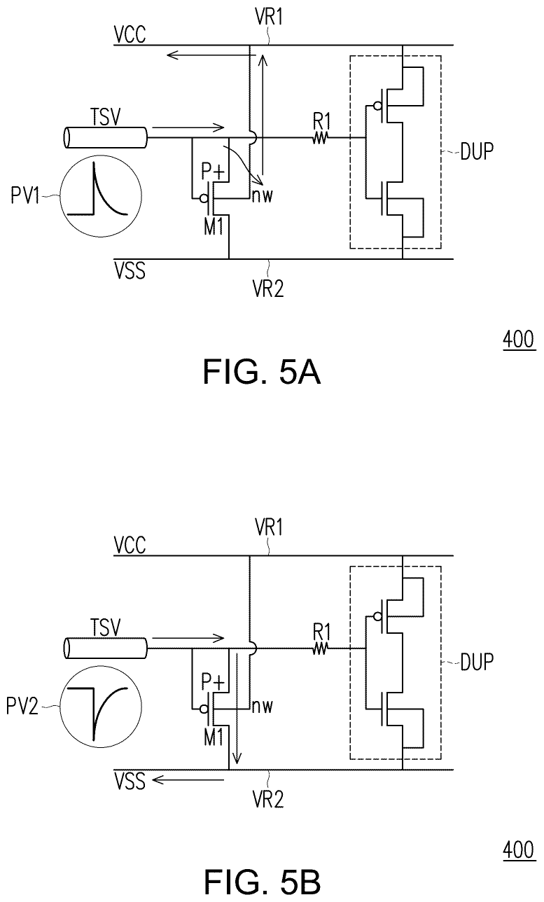

For details regarding the operation of the ESD protection circuit 400, refer to FIGS. 5A and 5B. FIGS. 5A and 5B show schematic diagrams of the ESD protection action of the ESD protection circuit according to an embodiment of the disclosure.

In FIG. 5A, when a surge voltage PV1 with a positive pulse is applied to the TSV, the surge voltage PV1 is applied to the source of transistor M1. Since the source of transistor M1 is P+ type, and the substrate of transistor M1 is N type, the P-N junction formed between the source and the substrate of transistor M1 can be turned on by the surge voltage PV1. In this way, the electrostatic discharge current corresponding to surge voltage PV1 can be discharged from the TSV through the source and substrate of transistor M1 to the first voltage rail VR1.

In FIG. 5B, when a surge voltage PV2 with a negative pulse is applied to the TSV, the surge voltage PV2 is applied to the gate of transistor M1. Since transistor M1 is a P-type transistor, transistor M1 can be turned on in response to the surge voltage PV2, forming a channel between the source and the drain. In this way, the electrostatic discharge current corresponding to surge voltage PV2 can be discharged from the TSV through the channel formed between the source and the drain of transistor M1 to the second voltage rail VR2.

From the above description, it is clear that the ESD protection circuit 400 of this embodiment can effectively provide a discharge path for the electrostatic discharge current when an electrostatic discharge event occurs, thereby effectively preventing the protected element DUP from being damaged.

In summary, the electrostatic discharge (ESD) protection structure of the disclosure allows the through-silicon via (TSV) connected to the input/output node to be formed in the substrate, thereby forming the gate of the transistor. By forming multiple heavily doped regions around the liner oxide layer surrounding the TSV, the source and the drain of the transistor are respectively formed. In this way, the electrostatic discharge current generated by the surge voltage applied to the input/output node can be discharged through the ESD protection structure to the voltage rails, effectively completing the electrostatic discharge protection for the circuit components.

What is claimed is:

1. An electrostatic discharge protection structure, comprising:
a substrate, coupled to a first voltage rail;
a through-silicon via, formed in the substrate;
a liner oxide layer, surrounding a side surface of the through-silicon via;
a first heavily doped region, formed in the substrate and contacting a first side of the liner oxide layer; and
a second heavily doped region, formed in the substrate and contacting a second side of the liner oxide layer,
wherein the first heavily doped region is coupled to the through-silicon via through a transmission conductive wire, and the second heavily doped region is coupled to a second voltage rail.

2. The electrostatic discharge protection structure according to claim 1, wherein a conductive polarity of the first heavily doped region is the same as a conductive polarity of the second heavily doped region, and the conductive polarity of the first heavily doped region is opposite to a conductive polarity of the substrate.

3. The electrostatic discharge protection structure according to claim 2, wherein the first heavily doped region and the second heavily doped region are P-type heavily doped regions, and the substrate is a N-type substrate.

4. The electrostatic discharge protection structure according to claim 1, wherein the through-silicon via is coupled to an input/output port.

5. The electrostatic discharge protection structure according to claim 1, wherein when a surge voltage with a positive pulse is applied to an input/output port, an electrostatic discharge current generated correspondingly is discharged through the first heavily doped region and the substrate to the first voltage rail.

6. The electrostatic discharge protection structure according to claim 5, wherein when a surge voltage with a negative pulse is applied to the input/output port, an electrostatic discharge current generated correspondingly is discharged through a channel formed between the first heavily doped region and the second heavily doped region to the second voltage rail.

7. The electrostatic discharge protection structure according to claim 1, further comprising:
at least one third heavily doped region, formed in the substrate and contacting a third side of the liner oxide layer; and
at least one fourth heavily doped region, formed in the substrate and contacting a fourth side of the liner oxide layer.

8. The electrostatic discharge protection structure according to claim 7, wherein the at least one third heavily doped region is coupled to the through-silicon via, and the at least one fourth heavily doped region is coupled to the second voltage rail.

9. The electrostatic discharge protection structure according to claim 1, wherein the first voltage rail is used to transmit a power supply voltage, and the second voltage rail is used to transmit a reference ground voltage.

10. An electrostatic discharge protection circuit, comprising:
a transistor, formed on a substrate, wherein a source of the transistor is coupled to a gate of the transistor and coupled to an input/output port, the substrate is coupled to a first voltage rail, and a drain of the transistor is coupled to a second voltage rail, the transistor comprising:
a through-silicon via, formed in the substrate and used to form the gate of the transistor;
a liner oxide layer, surrounding a side surface of the through-silicon via and used to form a gate oxide layer of the transistor;
a first heavily doped region, formed in the substrate and contacting a first side of the liner oxide layer, the first heavily doped region being used to form the source of the transistor; and
a second heavily doped region, formed in the substrate and contacting a second side of the liner oxide layer, the second heavily doped region being used to form the drain of the transistor.

11. The electrostatic discharge protection circuit according to claim 10, wherein a conductive polarity of the first heavily doped region is the same as a conductive polarity of the second heavily doped region, and the conductive polarity of the first heavily doped region is opposite to a conductive polarity of the substrate.

12. The electrostatic discharge protection circuit according to claim 10, wherein when a surge voltage with a positive pulse is applied to the input/output port, an electrostatic discharge current generated correspondingly is discharged through the source of the transistor and the substrate to the first voltage rail.

13. The electrostatic discharge protection circuit according to claim 10, when a surge voltage with a negative pulse is applied to the input/output port, the transistor is turned on, and an electrostatic discharge current generated correspondingly is discharged through a channel formed in the transistor to the second voltage rail.

14. The electrostatic discharge protection circuit according to claim 10, wherein the transistor further comprises:
at least one third heavily doped region, formed in the substrate and contacting a third side of the liner oxide layer; and
at least one fourth heavily doped region, formed in the substrate and contacting a fourth side of the liner oxide layer,
wherein the at least one third heavily doped region and the first heavily doped region jointly form the source of the transistor, and the at least one fourth heavily doped region and the second heavily doped region jointly form the drain of the transistor.

15. The electrostatic discharge protection circuit according to claim 14, wherein the at least one third heavily doped region is coupled to the through-silicon via, and the at least one fourth heavily doped region is coupled to the second voltage rail.

16. The electrostatic discharge protection circuit according to claim 10, wherein the first voltage rail is used to transmit a power supply voltage, and the second voltage rail is used to transmit a reference ground voltage.

17. The electrostatic discharge protection circuit according to claim 10, further comprising:
a resistor, coupled between a source of the transistor and a protected element.
